(19) United States
(12) Patent Application Publication
(10) Pub. No.: US 2002/0108743 A1
(43) Pub. Date: Aug. 15, 2002

(54) Porous media heat sink apparatus

(76) Inventor: Richard A. Wirtz, Incline Village, NV (US)

Correspondence Address: Kenneth D'Alessandro, Sierra Patent Group, Ltd., P.O. Box 6149, Stateline, NV, 89449, US

(21) Appl. No.: 09/734,526

(22) Filed: Dec. 11, 2000

(51) Int. Cl. H05K 7/20; H01L 23/26; F28F 7/00; H01L 23/34

(52) U.S. Cl. 165/185; 165/80.3; 165/907; 361/704; 174/16.3; 257/722

(57) ABSTRACT

A porous media heat sink usable as a small heat exchange device to air-cool a high power dissipation rate object in a low-noise environment. The heat sink comprises a thermally conductive base, a plurality of thermally conducting fins coupled to the base and oriented substantially normal or perpendicular to the base, and a plurality of thermally conductive porous media elements interleaved between the fins in a serpentine or sinusoidal configuration and arranged with respect to the heat sink base such that the longitudinal axis of the sinusoidal configuration is substantially normal to the base and substantially parallel to the fins. The base of the heat sink is thermally coupled to the component generating heat, typically a microprocessor package, to facilitate heat dissipation.

### BACKGROUND OF THE INVENTION

1. Field of the Invention

This invention pertains generally to devices and methods for thermal control, and more particularly to a porous media heat sink usable as a small heat exchange device for cooling micro-electronic packages and microprocessors.

2. Description of the Background Art

As the power of motherboards and hardware used in electronic packages increases, the cooling capacity requirements for these systems also increases. The demand for quieter computers and stringent EMC regulations has also accelerated the need for developing new devices to control the thermal output generated from these electronic packages. The requirement for extra cooling must be supplied by either a heat sink or the chassis of the computer system.

Heat sink devices augment convective cooling of electronic packages by increasing the effective surface area of the electronic package. In systems where noise considerations limit the size of the primary air mover of the electronic package, the design and materials utilized in a heat sink become crucial in the cooling of sensitive high-power electronics such as computers. Commercially available heat transfer devices having footprints of approximately 50 mm square typically result in thermal resistances of 0.5-2.5° C./Watt. Thermal resistance measurements are typically used to indicate the performance of heat sinks with similar size, and are determined from the temperature difference between the heat sink base and the surrounding air. Heat sinks with low thermal resistance values are considered to have better performance and heat transfer efficiency than comparable high thermal resistance heat sinks tested under similar conditions.

Microprocessor manufacturers have determined that heat sinks for the next generation of microprocessors will need to achieve thermal performance standards in which the thermal resistance is less than 0.2° C./Watt, with an air flow rate less than 30 cubic feet/ minute (cfm) to limit the noise of the system with a standard air flow pressure drop of approximately 0.25 inches water, across the heat sink. These specifications were derived from theoretical models for cooling 50 to 100 Watt microprocessors. Suitable heat sink devices having these properties have heretofore been unavailable.

Another factor that must be considered in designing heat transfer devices is the overall weight of the heat sink. There is a growing need for computers and other electronic devices to be portable and mobile, which requires the components in these machines to be as light as possible.

Compact heat exchangers invariably incorporate heat transfer augmentation technology at the fluid-solid interface to increase the performance of a heat sink. The more popular and well documented passive techniques include roughened walls, extended and modified surfaces, and displaced inserts. Roughness of the walls of a heat sink modifies the viscous sub-layer, and as a consequence affects the unit surface conductance “h”. Adding extended surfaces called fins to a heat sink primarily increases the heat transfer surface area, although some fin configurations also increase the unit surface conductance h. For example, strip-fins interrupt thermal boundary layer growth, leading to higher values of h. Inserts (for example, twisted tapes) modify the core flow in such a way as to increase heat transport at the wall. Geometric modification of the heat transfer walls may also accomplish this.

The use of a conductive porous media as the exchange matrix at the fluid-solid interface of a compact heat exchanger will also enhance performance. This technique offers several advantages over other heat transfer augmentation technologies. Porous media have a very high heat transfer surface area to volume ratio, can be easily fabricated, are inexpensive, and yet allow for potentially complex matrix shapes to be produced while allowing the opportunity to tailor the h−Δp (unit surface conductance−air pressure drop over the heat sink) characteristics of the surface to meet specific requirements and parameters needed for various electronic devices.

One measure of a high-performance heat exchange matrix is its heat transfer surface area-to-volume ratio, β=A/Vol. For example, a parallel plate heat exchanger has βₚ₁=1/H, where 2H is the plate spacing. When H=1 mm, βₚ₁ =1000 m⁻¹, while a typical offset strip-fin surface has β_{off-set}=2250 m⁻¹. By comparison, a porous matrix consisting of unconsolidated spherical particles of diameter d, and porosity ε, has a heat transfer area to volume ratio

βₚₒᵣₒᵤₛ=6(1−ε)/d

A typical value for a porous matrix, with d=1 mm and ε=0.4 is βₚₒᵣₒᵤₛ=3600 m⁻¹. Assuming the same heat exchanger volume, the porous matrix provides approximately 1.5 times more heat transfer surface than the offset strip-fin array, and 3.6 times more than an unenhanced plate surface. The use of smaller particles or a material having a lower porosity will result in even more favorable ratios.

The thermal conductance of a heat exchange surface is proportional to the product of the unit surface conductance of the fluid-solid interface and the heat transfer surface area, (hA). At a fixed coolant flow rate and heat exchanger frontal area, h will be approximately the same for different surface configurations. Therefore, significant increases in surface area A translates directly to either an increase in capacity or a reduction in exchanger size and weight.

A porous exchange matrix can be formed by gravity sintering metallic particles. Gravity sintering is essentially a casting process. Metallic particles are shaped (usually via tumbling), pre-tinned with a eutectic and flux agent, poured in a mold and heated to a temperature above the eutectic. The bonded piece is then removed from the mold. Innovative mold design will allow for highly complex yet inexpensive exchanger shapes. The process has been used for decades in the production of metallic filters and flame holders. More recently it has been used to form the wick for a flexible heat pipe used to cool the microprocessor of laptop computers, as well as some specialized heat exchanger cores. Liquid-coolers, having capacities exceeding 5000 Watt/cm², have been developed to cool the Gyrotrons in a fusion reactor, as well as laser cavity coolers having a capacity in excess of 6000 Watt/cm².

The use of porous media in heat sinks has become popular since they can increase performance while allowing the overall weight of the heat sink to be minimal. Porous media provides a large surface area which helps increase the efficiency of the heat sink. Unfortunately, porous media devices also have a few drawbacks. One drawback is the void fraction within the porous media which decreases the thermal conductivity of the porous media compared to solid thermal conductive material. Another problem with utilizing porous media in heat sink designs is that during the braising and production process of porous media devices, the alloy material produced decreases the thermal conductivity of the porous media. These drawbacks demonstrate the importance of the design and geometric shape of the porous media in optimizing the surface area and thermal conductance of a heat sink.

While heat sinks with porous exchange matrixes appear to be preferable for certain heat transfer applications, the shape and design of the porous media greatly effects the overall performance of porous media heat exchangers. One heat sink example which demonstrates the importance of porous exchange matrix shape and design is disclosed in U.S. Pat. No. 5,860,472, where the porous media is made of wired wrapped mandrel which is horizontally arranged in a finned sigmoid shape across the base of the heat sink. This design is capable of generating a thermal resistance of 0.287° C./Watt for a heat sink with base dimensions of 2.5″×3.5″ and a height of 2.5″. To achieve these thermal resistance values at an air pressure drop of 0.25 inch water, however, an air flow rate of 40 cfm across this heat sink is needed. This heat sink model does not meet the thermal resistance values that microprocessor manufacturers recognize as necessary to cool future high powered microprocessors. Additionally, the high air flow rate for this model requires use of a large, noisy fan to get the necessary air flow for adequate cooling.

At present, most microprocessor manufacturers would like to utilize heat sinks with the small footprint of 2.5″×3.5″ as noted above, a thermal resistance below 0.2° C./Watt, and an air flow rate less than 30 cfm at an operating pressure of 0.25 inch of water. These features, however, have not been achieved in currently available heat sink devices.

Accordingly, there is a need for a heat sink apparatus with a small foot print, which allows for adequate cooling of microprocessors with air flow rates below the maximum environmental air flow level standards, and which is generally capable of meeting the demands and specifications set by the microprocessor industry as stated above. The present invention satisfies these needs, as well as others, and generally overcomes the deficiencies found in the background art.

### SUMMARY OF THE INVENTION

The present invention is a porous media heat sink usable as a small heat exchange device to air-cool a high power dissipation rate object in a low-noise environment. The invention is particularly well suited for the cooling of micro-electronic package devices such as a microprocessor. The cooling capacity of the porous media heat sink of the invention provides a substantial advantage in cooling effectiveness over currently available heat sink devices.

The heat transfer apparatus of the invention comprises, in general terms, a thermally conductive base, a plurality of thermally conducting vertical fins coupled to the base and oriented substantially normal or perpendicular to the base, and a thermally conductive porous media interleaved between the vertical fins in a serpentine or sinusoidal configuration and arranged with respect to the heat sink base such that the longitudinal axis of the sinusoidal configuration is substantially normal to the base and substantially parallel to the fins. The base of the heat sink is thermally coupled to the component generating heat, typically a microprocessor package, to facilitate heat dissipation. The fins may be tapered in shape away from the base.

The present invention provides a novel vertical sigmoidal arrangement of porous media positioned between a plurality of vertical fins. The shape and design of the heat sink have a marked effect on the airflow pattern and the thermal dissipation performance of the invention.

The material utilized in manufacturing the base plate/fin plate assembly may comprise any material having suitable thermal conductivity, such as aluminum, copper, pyrolytic graphite or like conductive material. The fins and base of the heat sink may be integral portions of a single piece of thermally conductive material, or may be joined together via welding, thermally conductive adhesive, or other technique which provides good thermal conductivity between the base and fins. As an integral piece, the base and fin assembly can be formed by conventional molding or extrusion techniques.

In some preferred embodiments of the invention the fins comprise aluminum plates. Alternatively, flat plate heat pipes could be substituted for the aluminum fins, which could boost performance further. Pyrolytic graphite composites may also be used for the fins to save on weight and allow for more geometric flexibility in the molding and design.

The porous media may comprise a variety of materials, such as wrapped wired mandrel, wired mesh, or gravity sintered thermally conductive particles. The material of the thermally conductive permeable media can be aluminum, copper, pyrolytic graphite or any other conductive material that could be molded or formed into a porous matrix. Aluminum spheres are readily available and are inexpensive compared to other possible materials, and thus are preferable for low cost embodiments of the invention. Small aluminum spheres are already utilized by the microprocessor industry, which allows easy implementation of the present invention in the microprocessor industry. The aluminum spheres may be of uniform size, preferably approximately 1 mm diameter. The spheres may also have random sizes allowing the smaller spheres to fit between the larger spheres, thereby reducing the void fraction of the porous media. The thermally conductive particles need not be spherical, and may comprise spheroids, truncated cylinders, or other shapes. Particle sizes utilized in the porous media matrix will depend on the particular heat transfer application of the invention. In typical embodiments, the diameter of the spheres will be approximately 0.5-1.5 mm in diameter, although this size may vary according to the particular use of the invention.

One process of forming the shape of the porous media comprises taking the pre-tinned, conductive particles and pouring them into the fin-plate/base plate/assembly which is assembled together with casting-mold elements. After the porous media has been added to the fin-plate/base plate mold casting assembly, the assembly is vibrated to ensure proper packing of the particles into the assembly. The assembly is heated in an oven above the melt temperature of the tinning material; it is then cooled and the mold elements are removed. The porous media is shaped to the heat sink specification by electroplating and braising the particles together. Other methods which are known to those skilled in the art, may also be utilized to obtain the design and shape of the porous media matrix in accordance to the present invention.

The base of the heat sink apparatus should be thermally coupled to the heat source such that good thermal conduction is established between the heat sink base and heat source. Where the heat source is a microprocessor component, the base may be coupled to the microprocessor component by an interface material such as thermal grease, thermally enhanced Teflon or like thermally conductive material, which allow for sufficient heat transfer to the heat sink base. The heat sink can also be attached to the microprocessor component via substrate holes, interfacing with the thermal plate or attaching to the top of the microprocessor component. Support elements for the heat sink may or may not be required depending on the heat transfer application. These examples for coupling the heat sink to the electronic heat source are only representative configurations used in the microprocessor industry, and are not meant to be limiting in any way.

An object of the invention is to provide a heat exchanger capable of cooling high powered electronic packages under standard operating conditions.

Another object of the invention is to achieve thermal resistance values that are below 0.2° C./watt for a heat exchanger having the dimensions appropriate for a heat sink utilized for 50-100 watt microprocessors.

Another object of the invention is to keep the overall cost for a heat exchanger to a minimum by utilizing porous media material, which is readily available and inexpensive.

Another object of the invention is to minimize the weight of the heat sink while maintaining a high level of thermal dissipation performance.

Another object of the invention is to minimize the air flow rate needed to achieve satisfactory heat dissipation to meet acoustic noise standards.

Further objects and advantages of the invention will be brought out in the following portions of the specification, wherein the detailed description is for the purpose of fully disclosing the preferred embodiment of the invention without placing limitations thereon.

### BRIEF DESCRIPTION OF THE DRAWINGS

The present invention will be more fully understood by reference to the following drawings, which are for illustrative purposes only.

FIG. 1 is a perspective view of a heat sink apparatus in accordance with the invention.

FIG. 2 is a partially exploded perspective view of the heat sink apparatus of FIG. 1.

FIG. 3 is a top plan view of the heat sink apparatus of FIG. 1.

FIG. 4 is a front elevation view of the heat sink apparatus of FIG. 1.

FIG. 5 is a side elevation view in cross section of the heat sink apparatus of FIG. 4 take through line 5-5, shown together with a microelectronics package.

FIG. 6A is a schematic illustration of a porous wall attached to a plane surface.

FIG. 6B is a graphic representation of temperature distribution in the porous wall of FIG. 6A.

FIG. 7 is a schematic illustration of a section of porous media shown positioned at an angle θ in accordance with the present invention.

FIG. 8A is a graphical illustration of air pressure drop versus thermal resistance for the heat sink apparatus of FIG. 1 as embodied in the specific example of Table 1.

FIG. 8B is a graphical illustration of air pressure drop versus air volume flow for the heat sink apparatus of FIG. 1 as embodied in the specific example of Table 1.

FIG. 9 is a graphical illustration of normalized superficial mass velocity versus distance for the porous media section of FIG. 7.

### DETAILED DESCRIPTION OF THE INVENTION

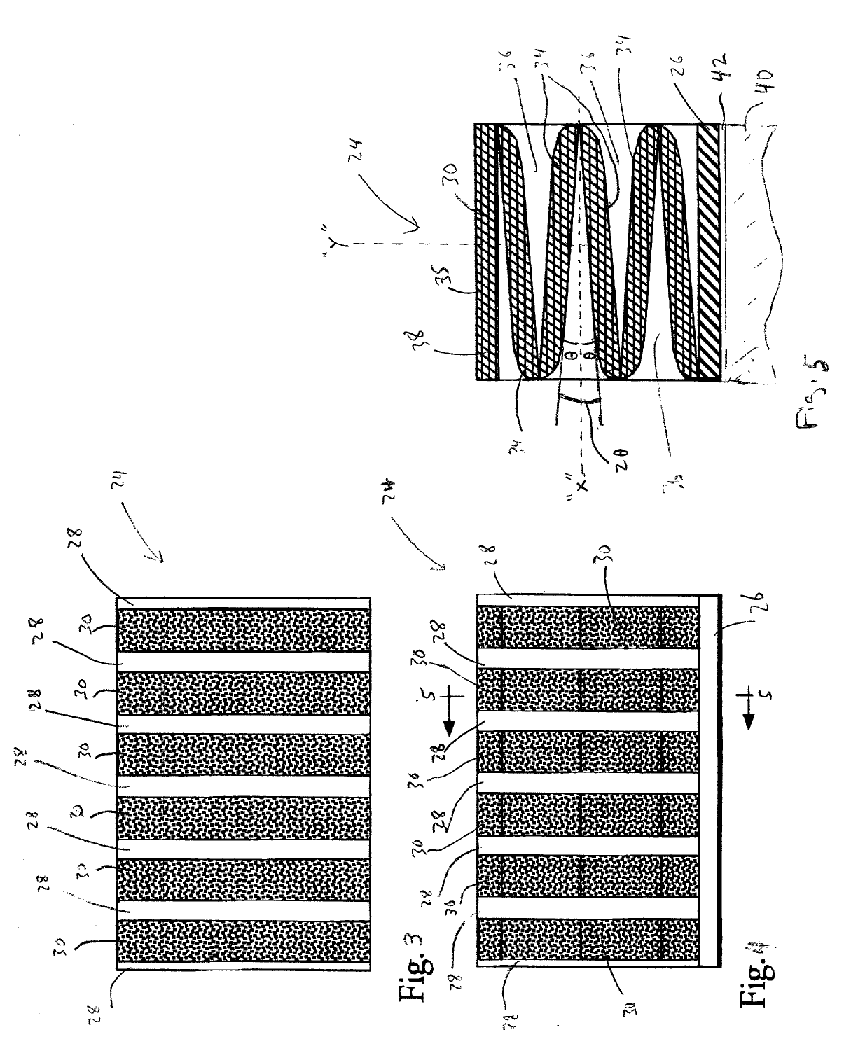

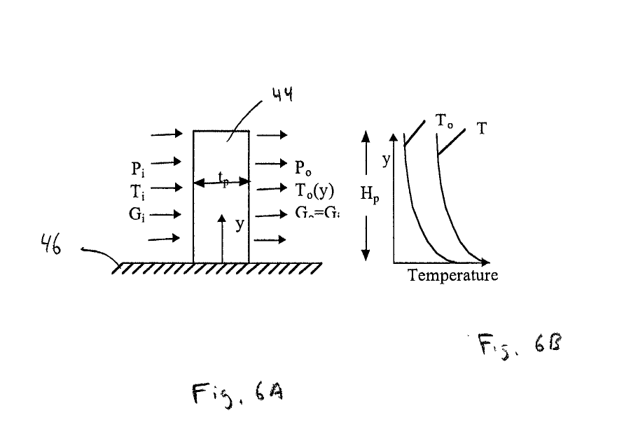

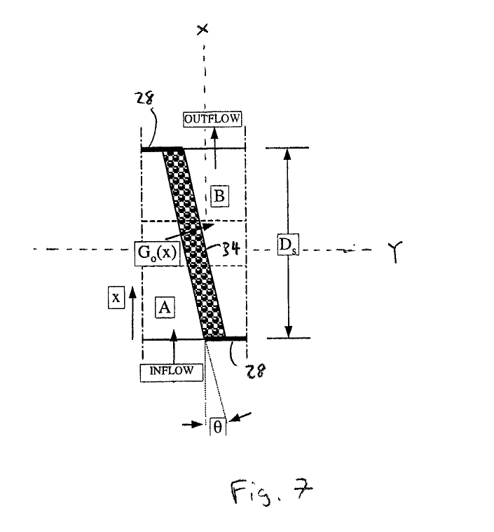

Referring more specifically to the drawings, for illustrative purposes the present invention is embodied in the apparatus shown generally in FIG. 1 through FIG. 5, as well as the graphical and schematic information shown in FIG. 6 through FIG. 9. It will be appreciated that the apparatus may vary as to configuration and as to details of the parts without departing from the basic concepts as disclosed herein. The invention is disclosed generally in terms of use with microprocessors and microelectronic devices. However, it will be readily apparent to those skilled in the art that the invention may be used for various thermal control applications.

Reference is now made to FIG. 1 through FIG. 5, wherein a heat sink apparatus 24 in accordance with the present invention is shown. The heat transfer apparatus includes a base 26, a plurality fins or plates 28 coupled to the base 26, and a plurality of porous media elements 30 interleaved between the fins 28. Base 26 preferably is substantially flat or planar in shape as shown.

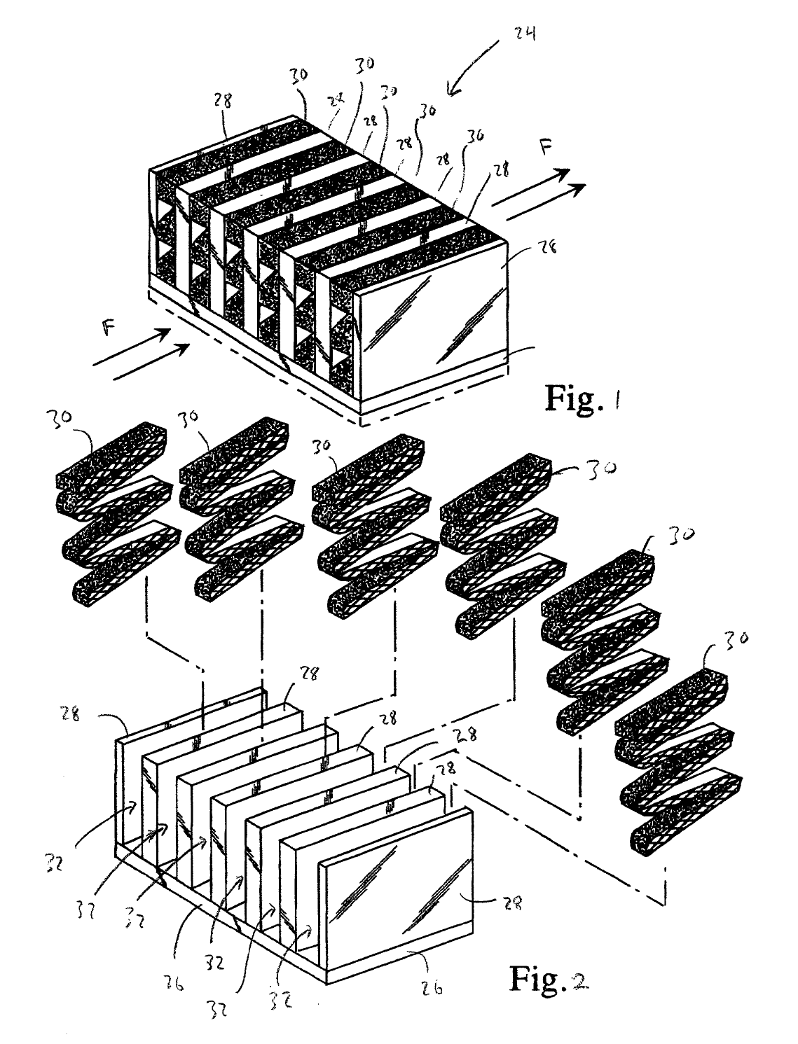

The fins 28 preferably are oriented such that they are substantially perpendicular or normal to base 26, such that when base 26 is positioned horizontally, fins 28 will be vertically oriented and extend upward from base 26. Fins 28 preferably are substantially parallel to each other as shown so that a plurality of slots 32 (FIG. 2) are defined between corresponding adjacent fins 28. The thickness and shape of base 26 and fins 28 may be varied for particular uses of the invention. In most preferred embodiments, base 26 and fins 28 will be substantially rectangular in shape as shown. In some embodiments fins 28 may be trapezoidal in shape.

The base plate 26 and fins 28 preferably comprise a material having high thermal conductivity, such as aluminum, copper or other metal or metal alloy, pyrolytic graphite epoxy or like high carbon thermally conducting composite material, or any other thermally conductive material. Fins 28 and base 26 of heat sink apparatus 24 may comprise integral portions of a single piece of thermally conductive material, or fins 28 and base 26 may be separate pieces which are coupled together via welding, thermally conductive adhesive, coupling hardware, or other technique which provides good thermal conductivity between the base 26 and fins 28. As an integral piece, the base 26 and fins 28 can be formed by conventional molding or extrusion techniques. In the preferred embodiments, fins 28 and base 26 preferably comprise solid aluminum. Fins 28 may alternatively comprise flat plate heat pipes. Fins 28 may be substantially straight as shown, or may tapered in shape from base 26 outward such that the ends of the fins 28 away from base 26 are thinner than the ends which are proximate to base 26.

Each of the slots 32 between adjacent fins 28 accommodates a porous media element 30. Porous media elements 30 preferably comprise elongated strips or sections of porous material which are coiled or otherwise arranged in a serpentine or sinusoidal pattern such that the elongated strips of porous material oscillate or “snake” back and forth within slots 32. Referring more particularly to FIG. 5, the sigmoidal shape of porous media elements 30 preferably define a plurality of folds or folded sections 34. The sigmoidal or serpentine shape of each porous media element 30 further defines a longitudinal axis “y”, with axis y, in the preferred embodiments, being oriented substantially perpendicular or normal to base 26, and substantially parallel with fins 28. The sigmoidal shape of porous media elements 30 also defines a plurality of elongated interstices or cavities 36 positioned between the curves or folds 34 of porous media elements 30, with interstices 36 being substantially elongated in the direction of a lateral axis “x”. Lateral axis x, as well as the direction of elongation of interstices 36, preferably is substantially parallel to the plane defined by base 26, and preferably is substantially perpendicular to longitudinal axis y.

The preferred serpentine shape of porous media elements 30 imparts an orientation to each fold or segment 34 such that each segment 34 is oriented by an angle θ with respect to lateral axis x, as seen most clearly in FIG. 5. Each segment 34 is generally oriented or angled in a direction which is opposite to each adjacent segment 34, such that adjacent segments 34 are “mirrored” about lateral axis x, such that adjacent segments are oriented with respect to each other by an angle 20, as shown in FIG. 5. The angle 2θ defines generally a taper angle for adjacent folds or segments 34 in each porous media element 30. The taper angle 2θ, which may be varied according to particular embodiments of the invention, is preferably an angle in the range of between approximately eight and twelve degrees, and more preferably between nine and ten degrees, as discussed further below. For reason of conserving space, the top our outermost segment or fold 35 of porous media element may be untapered or generally parallel to lateral axis x, as shown in FIG. 5.

The porous media elements 30 may generally comprise any thermally conductive porous material. The porous material is preferably in an “open cell” form to allow flow of air or other cooling fluid therethrough, but may comprise a closed cell porous material in some embodiments. In the presently preferred embodiments, the porous media elements 30 comprise small aluminum spheres 38 which have been sintered or melted together, preferably via gravity sintering as described further below. Gravity sintered aluminum spheres are readily available and provide inexpensive porous media with good thermal conductivity, and thus are preferable for low cost embodiments of the invention. Small aluminum spheres are already utilized by the microprocessor industry, which allows easy implementation of the present invention in the microprocessor industry. The aluminum spheres 38 may be of uniform size, preferably approximately 1 mm in diameter. The spheres may also have random sizes allowing the smaller spheres to fit between the larger spheres, thereby reducing the void fraction of the porous media. The thermally conductive particles need not be spherical, and may comprise spheroids, truncated cylinders, or other shapes. Particle sizes utilized in the porous media matrix will depend on the particular heat transfer application of the invention. In typical embodiments, the diameter of the spheres will be approximately 0.5-1.5 mm in diameter, although this size may vary according to the particular use of the invention.

Various other materials are contemplated for use in the porous media elements 30 of the invention. The porous media elements 30 may alternatively comprise, for example, thermally conducting foam materials, wrapped wired mandrel, 3-dimensional wire meshes, laminated screens, or sintered thermally conductive particles generally. The material of the thermally conductive permeable media 30 can be aluminum, copper, pyroytic graphite or any other conductive material that could be gravity sintered or molded into a serpentine or sigmoidal configuration. The use of screen laminates and 3D wire meshes are advantageous in that they can be easily tailored to control the porosity or density of elements 30, and can be oriented or configured to optimize thermal conductivity in specific directions. Open cell aluminum foam or other metal foams also provide good thermally conductive porous media elements 30. Yet another preferred material for porous media elements is open cell graphite foam. One such light weight porous graphitic foam suitable for use with the invention is PocoFoam™, made by Poco Graphite, Inc. of Decatur, Tex.

A preferred process for forming the shape of the porous media elements 30 involves gravity sintering, as noted above. This technique generally comprises providing pre-tinned, thermally conductive particles or spheres 38, and providing casting mold elements (not shown) which define the sigmoidal or serpentine shape of porous media elements 30, with alternating folds 34 and interstices 36 extending outward from base 26 along longitudinal axis A. The tinning (not shown) is generally formed by electroplating a conventional brazing solder or like material onto spheres 38. The mold elements are positioned in the slots 32 between fins 28 to define sigmoidal shaped cavities. The pre-tinned spheres 38 then are poured and pouring into the slots 32 according to the shape imparted by the mold elements, and the assembly is vibrated to ensure proper packing of the particles 38.

The assembled base 26, fins 28, spheres 38 and mold elements are then heated in an oven above the melt temperature of the tinning material so that the spheres 34 are fused together to form porous media elements 30 in slots 32. The assembly is then cooled and the mold elements are removed to provide the heat sink apparatus 24. Porous media elements 30 may be alternatively formed from other methods which are known to those skilled in the art.

In operation, the base 26 of heat sink apparatus 24 is thermally coupled to a heat source 40 (FIG. 14) such as a microelectronics package, so that good thermal conduction is established between the heat sink base 26 and heat source 40. Where the heat source 40 is a microprocessor component, the base 26 may be coupled thereto by a layer of interface material 42 such as thermal grease, thermally enhanced Teflon, or like thermally conductive material, which allows for sufficient heat transfer from the heat source 40 to the heat sink base 26. The heat sink apparatus can also be attached to the microprocessor component 40 via substrate holes (not shown) and/or support elements. Numerous arrangements for coupling a heat sink to an electronic heat source are known in the art, and the above are only representative configurations used in the microprocessor industry.

Once thus attached to the heat source 40, air flow or other cooling fluid, as shown by arrows F (FIG. 10), is passed laterally through slots 32 and porous media elements 30 to effect cooling via heat transfer from fins 28 and porous media elements 30 to the air or other cooling fluid passing therethrough. The direction of coolant flow as indicated by arrows F is substantially parallel to base 26 the direction of slots 32. Heat is conducted into the (heat spreader) base 26, up through the fin-plates 28, and into the porous media elements 30. The coolant (air) is ducted to the heat sink apparatus 24 by conventional means such as a fan, and the coolant passes through the porous media elements 30. Most of the heat transfer provided by the apparatus 24 is by convection within the porous media elements 30.

The shape and configuration of porous media elements 30, wherein the longitudinal axis A of each signmoidal shaped element 30 is oriented substantially normal to base 26, and the interstices 36 in elements 30 are oriented substantially parallel to base 26, provides particularly advantageous cooling effects for use with microelectronic heat sources. In most microelectronic applications, the heat source will be mounted on a mother board, and the fins 28 will extend upward or outward from the motherboard and microelectronic heat source attached thereto. A fan (not shown) is positioned to provide air flow through the slots 32 and porous media elements 30.

In a small footprint embodiment of the heat sink apparatus 24 as used with microelectronic heat sources, as a specific example, the base 26 (and thus the apparatus 24) will have dimensions of no greater than approximately 2.5 inches width by 3.5 inches length, and the combined fins 28 and base 26 will have a height of no greater than 2.5 inches. With these dimensions, effective cooling is achieved with a lateral air flow as shown by arrows F having an operating air pressure drop across heat sink 24 of approximately 0.25 inches water or less, with a lateral air flow volume of approximately 30 cubic feet per minute or less. These air flow characteristics are highly desirable in view of noise and environmental constraints imposed on microelectronic devices. The heat sink apparatus 34 in this specific configuration can provide a thermal resistance of less than approximately 0.2° C./Watt. The above dimensions and air flow characteristics represent only one specific example of the invention, and should not be considered limiting.

The present invention will be more fully understood by reference to the following specific examples, wherein the base plate 26 and fin plates 28 comprise an integral unit made of aluminum, and the porous media 30 each comprise a mass of unconsolidated spherical aluminum particles that are gravity sintered together and bonded (via aluminum brazing) to the base 26 and fin plates 28 to define open cell porous media elements 30.

The invention takes advantage of the fact that porous media typically have a very high heat transfer surface area to volume ratio, β. For example, a conventional plate-fin heat exchanger has βₚ₁=1/H, where 2H is the plate spacing. When H=1 mm, βₚ₁=1000 m⁻¹. A typical offset strip-fin exchange matrix typically has β_{off}˜2500 m⁻¹. In contrast, a porous matrix of unconsolidated spherical particles of diameter d and porosity ε has βₛₚ=6(1−ε)/d . A typical value for porosity is ε=0.4, so with spheres having a diameter d=1 mm, βₛₚ=3600 m⁻¹. For the same volume of exchanger, the spherical particle porous media provides approximately 1.5 times more heat transfer surface than an offset strip-fin array, and 3.6 times more than a flat plate-fin array.

The invention results generally in low coolant flow rates, leading to quiet operation. With careful control of coolant pressure drop via the serpentine configuration of the porous media elements 30, high thermal performance with low coolant flow rates, approaching the thermodynamic limit, can be achieved, resulting in quiet operation. In this specific example, the base 26 of apparatus 24 has a width Wₛ=3.5″×diameter Dₛ=2.5″ (inch) footprint, and the apparatus 24 has a height Hₛ=1.5″ (inch) total height (excluding a 0.25″ thick base 26). With seven plate-fins 28, a base-to-ambient thermal resistance of R_{b-a}=0.16° C./Watt is provided with an airflow rate of 25 cfm (cubic feet per minute), when the pressure drop across the apparatus 24 is 0.25 inch H₂O. In this specific example, the porous media provides a relatively dense structure. As a consequence, the porous media elements 30 effectively muffle sound. Thus, a cooling or system fan (not shown) may be “sandwiched” or interposed between two adjacent porous media heat sinks 24 so that acoustic emissions from the fan are minimized.

Fabrication of the apparatus 24 as provided in this specific example, with base plate 26 and fin plates 28 being integral aluminum parts and the porous media 30 comprising unconsolidated spherical aluminum particles gravity sintered together and bonded to the base 26 and fin plates 28, can be easily carried out by techniques which are well known and readily available in the microelectronics industry. Fabrication generally involves bonding, extrusion, and molding (gravity sintering) of aluminum as noted above. Aluminum bonding (brazing) and extrusion are processes common to the heat sink industry. Formation of the porous media elements 30 is essentially a casting process. Aluminum particles are coated with an AlSi alloy-bearing flux and loaded into a mold/extruded aluminum form. The assembly is heated to the brazing temperature and then cooled and mold pieces are removed.

The heat transfer provided by the invention will be more fully understood by reference to FIG. 6A, wherein a feature of the invention is shown as a fin-like porous wall 44 that protrudes from an isothermal surface 46. The wall 44 has height Hₚ, length Lₚ, and thickness tₚ. The physical properties of the porous wall 44 are ε, β, the effective thermal conductivity kₑ, and its composition. The temperature of the wall 44 is T(y), and it is cooled by a coolant (not shown) that flows through it as indicated by arrows. The coolant, at uniform temperature Tᵢ and pressure, pᵢ, approaches the wall 44 with mass velocity, Gᵢ [kg/s per m²]. The coolant exits the wall 44 at uniform pressure, Pₒ, temperature, Tₒ(y) and mass velocity, Gₒ=Gᵢ. FIG. 6B illustrates generally the temperature distribution of the porous wall 44 and the coolant.

A performance model for porous wall heat transfer is described in detail by Wirtz in “A Semi-Empirical Model for Porous Media Heat Exchange Design”, Proceedings, American Society of Mechanical Engineers National Heat Transfer Conference, Baltimore Md., Aug. 10-12 (1997). Assuming one-dimensional conduction in the y-direction and one-dimensional flow of coolant with respect to wall 44, then the mass and momentum equations relate the pressure drop across the wall to the mass velocity. For spherical particles, the relationship is

$$\frac{{p}_{1} - {p}_{0}}{{G}_{0}^{2} / ρ} = \frac{( 1 - ϵ ) {t}_{p}}{d} \frac{150 ( 1 - ϵ )}{Re} + 1.75 \qquad ( 1 )$$

where Re=Gₒ d/μ is the particle Reynolds number. Fourier's Law is provided as

$$q = - {k}_{e} {t}_{p} {L}_{p} \frac{ⅆ T}{ⅆ y} \qquad ( 2 )$$

where kₑ is the effective thermal conductivity of the porous media. For bonded unconsolidated spherical particles, kₑ is typically 10%-20% of the base material thermal conductivity. Energy equations for both the fluid and solid phases may be determined and coupled with the particle heat transfer coefficient, h. Empirical correlations for h are found in the literature. For example, Wakao and Kaguei, “Heat and Mass Transfer in Packed Beds, Gordon and Breach Science Pub. [1982], give a good correlation for convection in beds of unconsolidated spherical particles.

Assuming the top of the wall 44 in FIG. 6A is adiabatic, with the temperature at the base, T(0), the equivalent wall conductance is defined as Uₚ=q(0)/Lₚtₚ[T(0)−Tᵢ]. Then, a solution is provided by

$$\frac{{U}_{p} {H}_{p}}{{k}_{e}} = m {H}_{p} tan h [ m {H}_{p} ] , m = \sqrt{\frac{{c}_{p} {G}_{0}}{{k}_{e} {t}_{p}} ( 1 - {e}^{- NTU} )} , NTU = {St}_{p} β t \qquad ( 3 )$$

where Stₚ=h/cₚGₒ is the particle Stanton number. Since there could be a thermal resistance at the porous wall-to-fin plate interface, the overall fin-plate-to-porous wall equivalent conductance is written as

$${U}_{tot} = \frac{{U}_{p}}{1 + {U}_{p} {R}_{i}^{″}} \qquad ( 4 )$$

where R″ᵢ is the interfacial resistance.

Consider now a segment or portion of a heat sink consisting of a fin-plate of thickness tₛ, depth Dₛ, and height Hₛ, bounded by porous wall segments (thickness tₚ, length Lₚ, height Hₚ). For un-tapered fin-plates, the spacing between fin-plates is 2Hₚ. The fin-plate acts as a fin having surface conductance equal to

$${U}_{f} = \frac{{t}_{p} {L}_{p}}{{D}_{s} {H}_{s}} {U}_{tot} + \overline{1} - \frac{{t}_{p} {L}_{p}}{{D}_{s} {H}_{s}} {√}_{{√}_{← \vert}} {U}_{0} \qquad ( 5 )$$

where Uₒ is the surface conductance on the exposed fin-plate surface. For a given fin-plate taper, the “fin effectiveness”, η_{f} may be determined. For example, for rectangular fins (no taper) having an adiabatic tip,

$${η}_{f} = \frac{tan h ( {𝒳}_{f} )}{{𝒳}_{f}} , {𝒳}_{f} = \sqrt{\frac{2 {U}_{f} {H}_{s}^{2}}{{k}_{f} {t}_{f}}} \qquad ( 6 )$$

Then, the total heat transfer for N_{f} fin-plates is

q_{f}=(N_{f}−1)η_{f}U_{f}HₛDₛ[T_{f}(0)−Tᵢ] (7)

If it is assumed that there is no spreading resistance in the heat sink base, then T_{f}(0)=Tₛ, the base temperature, and the heat sink base-to-ambient temperature can be estimated as

$${R}_{b - to - amb} = \frac{⌊ {T}_{s} - {T}_{i} ⌋}{{q}_{f}} \qquad ( 8 )$$

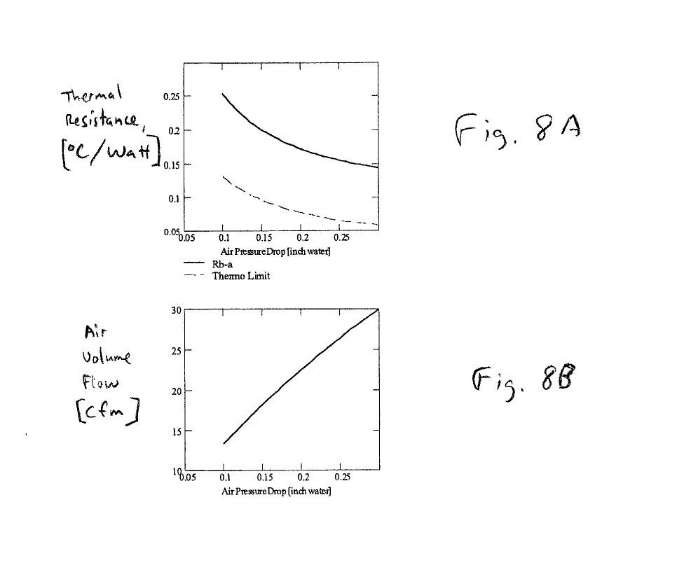

The above performance model can be used to estimate performance assuming that Gₒ is uniform everywhere. Referring now to FIG. 7, a schematic view of a segment 34 of porous media element 30 is shown bonded to fin-plates 28. The porous wall 48 has thickness tₚ and length Dₛ/cos θ where θ is the flow channel taper half-angle. The angle θ as shown in FIG. 7 is generally the same as that shown in FIG. 5, and the lateral and longitudinal x and y axes of FIG. 5 are shown in FIG. 7 as well for clarity. Coolant flows in via region A, through the porous wall, and it exits through region B. The dot-dash lines in FIG. 7 are lines of symmetry. For given overall pressure drop from inlet to outlet, a certain value of θ or range of θ will result in a uniform superficial mass velocity, Gₒ.

In determining the optimum value for θ, the flow regime is discretized into finite volumes (one such volume is shown in FIG. 7). Assuming one-dimensional, invisid flow in regions A and B, mass/x-momentum conservation equations for each segment of regions A and B can be coupled together via Eq. (1), the mass/momentum equation for flow through the porous wall. Simultaneous solution of the system gives the superficial mass velocity distribution for given overall pressure drop. Analysis shows that the inflow/outflow channels preferably are tapered as shown in FIG. 1 through FIG. 5 and FIG. 7. The taper angle for approximately uniform Gₒ is typically in the range of θ˜4°-6°. Consequently, the porous wall “serpentine” layout for porous media elements 34 as shown in FIG. 1 through FIG. 5 is such that a taper angle 2θ of between approximately 8° and 12° is preferred. More preferably, the taper angle 2θ is in the range of between approximately 9° and 10°, and most preferably in the range of between approximately 9.5° and 9.7°.

Table 1 summarizes the physical attributes of the heat sink apparatus 24 of FIG. 1 through FIG. 5 as embodied in an aluminum device having a 3.5″×2.5″ footprint that is 1.5″ tall (excluding the base plate thickness), with seven 0.125″ thick fin-plates separating six 3.8 mm thick serpentine-configuration spherical-particle porous media heat exchange matrices 34. The heat sink apparatus in the example of Table 1 has a total area of approximately 525 in², and a total mass is approximately 275 gm.

TABLE 1
Heat sink configuration.

| Item | Specification |
|---|---|
| Material | Aluminum, kₐₗ = 200 W/mK |
| Size | Hs = 1.5″ (excludes base), Ws = 3.5″, Ds = 2.5″ |
| Fin-Plates | 7 al fins: 6 @ 0.125″ thick, 2 ends @ 0.0625″ thick |
| | space between plates: 2Hₚ = 0.458″ |
| Porous media | Al spheres, d = 1 mm, ε = 0.39, kₑ = 20 W/mK |
| Porous wall layout | 6 interleaved serpentine units with 5 zigzag elements |
| | per fin-plate surface, tₚ = 3.8 mm, 20 = 9.6° |
| | Total length: Lₚ = 4.51 m, Heat transfer surface: |
| | 490 in² |
| R″₁ | d/(1-ε)kₑ (this assumes a good braze-bond |
| | between the porous wall and fin-plate) |
| Fin-plate surface | Uₒ = 0 |
| conductance, Uₒ | |
| Mass | 273.5 gm (excluding base plate) |

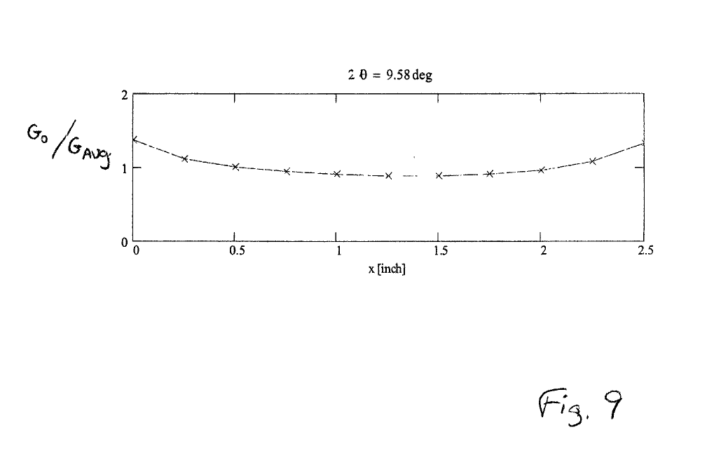

The performance of the specific example heat sink of Table 1 is illustrated in FIG. 8A and FIG. 8B. FIG. 8A shows the base-to-ambient thermal resistance (Eq. 8) as a function of pressure drop across the heat sink, while FIG. 8B shows the corresponding volume flow of air. Also shown in FIG. 8A (dashed line) is the thermodynamic limit.

FIG. 8A and FIG. 8B indicate that at an applied pressure drop of 0.25 inch H₂O, the base-to-ambient thermal resistance is 0.156° C./watt with an air flow rate of 26.3 cfm. At this flow rate, the thermodynamic limiting base-to-ambient thermal resistance is 0.067° C./watt. It is interesting to note that at this pressure drop and flow rate,

(UₚLₚtₚ)⁻¹=0.1 C°/watt,

so that incorporation of more highly conductive fin-plates (for example, flat-plate heat pipes), plus total elimination of the porous wall-to-fin-plate interfacial resistance will improve performance by about 36%. It is contemplated that the specific example of Table 1 may be further optimized to provide even better characteristics.

FIG. 9 shows the superficial mass velocity distribution along an adjacent pair porous wall elements 34. A passage taper angle, 2θ=9.6° results in an approximately uniform flow distribution.

Accordingly, it will be seen that this invention provides a porous media heat sink usable as a small heat exchange device to air-cool a high power dissipation rate object in a low-noise environment. Although the description above contains many specificities, these should not be construed as limiting the scope of the invention but as merely providing an illustration of the presently preferred embodiment of the invention. Thus the scope of this invention should be determined by the appended claims and their legal equivalents.

1. A heat sink apparatus, comprising:
(a) a thermally conducting base;
(b) a plurality of thermally conducting fins joined to said base and extending outward from said base; and
(c) a plurality of thermally conducting porous media elements positioned between corresponding ones of said plurality of fins.

2. The heat sink apparatus of claim 1, wherein each said porous media element has a serpentine configuration which defines a longitudinal axis, said longitudinal axis extending outward from said base.

3. The heat sink apparatus of claim 2, wherein said plurality of fins are substantially parallel to each other, and said longitudinal axis of each said porous media element is substantially parallel to said plurality of fins.

4. The heat sink apparatus of claim 2, wherein said serpentine configuration defines a plurality of folds and a plurality of interstices in each said porous media element.

5. The heat sink apparatus of claim 1, wherein said thermally conducting fins are tapered in thickness from said thermally conducting base extending upward.

6. The heat sink apparatus of claim 1, wherein said porous media elements are made from a material selected from thermally conducting particles, thermally conducting wire mesh, thermally conducting laminated screen, or thermally conducting foam.

7. The heat sink apparatus of claim 4, wherein adjacent ones of said plurality of folds are oriented with respect to each other by a taper angle 2θ which is in the range of between approximately eight degrees and twelve degrees of angle.

8. The heat sink apparatus of claim 1, wherein said base is configured to be thermally interfaced with a microelectronic heat source.

9. The heat sink of claim 1, wherein said plurality of fins are oriented substantially perpendicular to said base.

10. A heat sink apparatus, comprising:
(a) a thermally conducting base;
(b) a plurality of thermally conducting fins coupled to said base and extending outward therefrom; and
(c) a plurality of thermally conducting porous media elements interleaved between said plurality of fins, each said porous media element comprising an elongated strip arranged in a sigmoidal configuration.

11. The heat sink apparatus of claim 10, wherein said sigmoidal configuration of said porous media elements defines a plurality of folded segments and a plurality of interstices in said elongated strip of each said porous media element.

12. The heat sink apparatus of claim 11, wherein said plurality of fins are substantially parallel to each other.

13. The heat sink apparatus of claim 10, wherein said sigmoidal configuration of each said porous media element defines a longitudinal axis, said longitudinal axis substantially perpendicular to said base.

14. The heat sink apparatus of claim 10, wherein said thermally conducting fins are tapered in thickness from said thermally conducting base extending upward.

15. The heat sink apparatus of claim 10, wherein said base is configured to be thermally interfaced with a microprocessor.

16. The heat sink apparatus of claim 10, wherein said porous media elements are made from a material selected from thermally conducting particles, thermally conducting wire mesh, thermally conducting laminated screen, or thermally conducting foam.

17. The heat sink apparatus of claim 11, wherein said plurality of folded segments are configured such that adjacent said folded segments are oriented with respect to each other by a taper angle 2θ which is in the range of between approximately eight degrees and twelve degrees of angle.

18. A heat sink apparatus, comprising:
(a) a thermally conducting base;
(b) a plurality of thermally conducting fins coupled to said base, said plurality of fins oriented substantially parallel to each, said plurality of fins defining a corresponding plurality of slots between adjacent said fins, said slots being substantially parallel to each other; and
(c) a plurality of thermally conducting porous media elements, each said porous medial element positioned in a corresponding one of said slots each said porous media element comprising an elongated strip of porous material arranged in a sinusoidal configuration such that said elongated strip includes a plurality of folds separated from each other by a plurality of interstices.

19. The heat sink apparatus of claim 18, wherein said plurality of fins are oriented substantially perpendicular to said base.

20. The heat sink apparatus of claim 19, wherein said sinusoidal configuration of each said porous media element defines a longitudinal axis, said longitudinal axis substantially perpendicular to said base.

21. The heat sink apparatus of claim 20, wherein said sinusoidal configuration of each said porous media element defines a lateral axis, said lateral axis perpendicular to said longitudinal axis, said interstices oriented in a direction which is substantially parallel to said lateral axis.

22. The heat sink apparatus of claim 18, wherein said thermally conducting fins are tapered in thickness from said thermally conducting base extending upward.

23. The heat sink apparatus of claim 18, wherein said porous media elements are made from a material selected from thermally conducting particles, thermally conducting wire mesh, thermally conducting laminated screen, or thermally conducting foam.

24. The heat sink apparatus of claim 18, wherein said plurality of folds are configured such that adjacent said folds are oriented with respect to each other by a taper angle 2θ which is in the range of between approximately eight degrees and twelve degrees of angle.
